(19) United States
(12) Patent Application Publication
(10) Pub. No.: US 2016/0341770 A1
(43) Pub. Date: Nov. 24, 2016

(54) METHOD AND SYSTEM FOR DYNAMIC EXTRACTION OF PULSES IN A NOISY TIME SIGNAL

(71) Applicant: COMMISSARIAT À L'ÉNERGIE ATOMIQUE ET AUX ÉNERGIES ALTERNATIVES, Paris (FR)

(72) Inventors: Yoann MOLINE, Saclay (FR); Gwenole CORRE, Saint Aubin (FR); Mathieu THEVENIN, Saclay (FR); Thomas PEYRET, Massy (FR)

(73) Assignee: COMMISSARIAT A L'ENERGIE ATOMIQUE ET AUX ENERGIES ALTERNATIVES, Paris (FR)

(21) Appl. No.: 15/112,976

(22) PCT Filed: Jan. 20, 2015
(86) PCT No.: PCT/EP15/50927

§ 371 Date: Jul. 20, 2016

(30) Foreign Application Priority Data
Jan. 23, 2014 (FR) 14 50568

(51) Int. Cl. G01R 19/04; H03K 5/08; H03K 5/1532

(52) U.S. Cl. CPC G01R 19/04; H03K 5/1532; H03K 5/082

(57) ABSTRACT

A system for processing a noisy time signal having a set of pulses of different amplitude and duration, and a method implemented by the system. The system includes a processor processing the signal acquired by a detector to detect the pulses, the processing being configured to perform a derivation of the acquired signal and compare the derived acquired signal with a pulse start detecting threshold to detect a pulse when the derived acquired signal is greater than the threshold. The processor is further configured to dynamically adapt the threshold to the noise level affecting the derived acquired signal.

### TECHNICAL FIELD

The field of the invention relates to detecting and extracting pulses in a noisy time signal having a set of pulses of different amplitude and duration. The invention is particular applied in the field of nuclear instrumentation (especially in gamma and X spectrometry, in neutron-gamma discrimination, or in neutron counting), in the field of medical signal analysis (electrocardiograms, electro-encephalograms), or also in the field of radar detection.

### STATE OF PRIOR ART

In the case of a nondeterministic arrival of pulses, the density of received pulses is variable, able to vary from a few counts per second to several thousand counts per second. The real-time processing of pulses is then difficult to be performed. Moreover, several receiving channels can acquire pulses. It is then often necessary to compare the pulses coming from these channels, especially to determine with accuracy the duration separating them. The required calculation capacities, as well as the type of processings to be performed, can then automatically vary depending on the cases.

It is known to digitise, after pre-amplification, the signal acquired by a detector and to process the signal thus digitised using digital components in charge of performing the extraction of pulses and restitution of the extracted information as tables of samples. This processing is composed of two main steps.

The first step relates to the signal shaping(s). The purpose is to overcome at a maximum the evolution of the signal, its baseline and the electronic noise over time to facilitate setting-up of one or more fixed detecting thresholds parameterised before measurement by the user as a function of the very characteristics of the signal.

This first step depends on the detector, on the pre-amplifier as well as on the signals to be processed and imposes the total (anti-noise, anti-pile-up filter) or partial (restoration of the baseline) deformation of the signal. When the pulses representative of the information to be extracted cross the detecting threshold, the processings are executed to extract the desired information (maximum amplitude, counting).

This approach thus requires that the user knows beforehand part or all of the information he/she wants to extract. By way of example, if the user wants to detect a source which can be characterised by its high energies, he/she is permitted to place the threshold quite high. But this is not possible in applications where the source(s) to be characterised is/are not known, so that the threshold must therefore always be close to the noise to be able to detect all the energies. On the contrary, the user must avoid at a maximum to detect noise, which requires, by ignorance of the noise evolution, a detecting threshold to be set high enough. For this reason, part of the low energy information can be lost (the threshold being too high) whereas another part of the information can be inaccurate (the threshold being too close to the noise).

The second step relates to windowing of the information to be processed as part of an observation regarding the shape (neutron-gamma discrimination) or an energy calculation (area, duration above a threshold). Indeed, the conventional approach enabling the observation or backup of one or more pulses consists in using the method set forth in the previous paragraph, that is the use of a step for shaping and parameterising one or more fixed detecting thresholds. When the decrease of the pulse to be processed falls below the threshold defined by the user, the backup and/or processing of the pulse end.

This approach also does not take into account the evolution of the signal, of its baseline, and of the noise over time. Thus, if the signal is not first deformed, windowing the pulse randomly ends: either the window of the pulse is too short since the present noise is detected by the threshold, or the evolution of the baseline is such that the signal will no longer fall below the fixed threshold or, on the contrary, will fall too early. Due to this, part of the information can be lost or even false.

Another solution to isolate the pulses from the remainder of the signal consists in using a time windowing, that is instead of a pulse end detection threshold, a window can be opened from the first pulse detection with the aim of covering all the pulse. Nevertheless, this solution forces the user to set this parameter manually, and therefore to provide a window the size of which is large enough to be able to record the largest pulses. Due to this, in the presence of small pulses, many useless pieces of information are stored, reducing the quality of the results. Moreover, if several pulses, piled up or not, are in this window, they are considered and processed as a single pulse, thus distorting the results.

In order to make the detection of a pulse independent of the non-linearity of the baseline, it has been suggested, as part of the SPADIC (“Self-triggered Pulse Amplification and Digitization asIC”) project to base oneself on the derivative of the observed signal (that is an implementation of a high-pass filter) in order to decide whether to consider or not the presence of a pulse in this signal, and to enable pulse pile-ups to be detected. However, this suggestion is not free of the abovementioned drawbacks regarding the prior shaping of the signal and the windowing by fixed parameterised thresholds before measurement by the user.

### DISCLOSURE OF THE INVENTION

The aim of the invention is to overcome these drawbacks so as not to deteriorate the quality of the information relating to the pulses that can be extracted from a noisy time signal. To do so, it provides a method for processing a noisy time signal having a set of pulses of different amplitude and duration, comprising a step for processing the signal acquired by a detector to detect the pulses, said processing comprising calculating a derivative of the acquired signal and comparing the derivative of the acquired signal with a threshold to detect a pulse when the derivative of the acquired signal is greater than the threshold, characterised in that the threshold is dynamically adapted to the noise level affecting the derivative of the acquired signal.

Certain preferred but non-limiting aspects of the method are as follows:

it comprises calculating a standard deviation of the noise affecting the derivative of the acquired signal and dynamically adapting the threshold as a function of the calculated standard deviation;

calculating the standard deviation of the noise affecting the derivative of the acquired signal comprises smoothing the acquired signal by a low-pass filter, calculating a differentiated signal by subtracting the smoothed signal from the acquired signal, deriving the differentiated signal, and calculating the standard deviation of the derived differentiated signal;

it further comprises, further to detecting a pulse, tracking the derivative of the acquired signal to determine the location of the pulse peak;

it further comprises identifying the duration separating the pulse peak and an amplitude of the acquired signal corresponding to a predetermined ratio of the amplitude of the pulse peak;

the amplitude of the pulse peak is determined by comparing the amplitude of the pulse peak with the amplitude of the acquired signal stored before the derivative of the acquired signal exceeds the threshold;

it comprises storing the acquired signal from the detection of the pulse until a predetermined multiple of said duration from the pulse peak;

it comprises tracking the derivative of the acquired signal to detect a new pile-up pulse when the derivative of the acquire signal exceeds the threshold, determining the location of the new pile-up pulse peak, identifying the duration separating the new pulse peak from an amplitude of the acquired signal corresponding to a predetermined ratio of the amplitude of the new pile-up pulse peak, and storing this acquired signal until a predetermined multiple of said duration from the new pile-up pulse peak;

it further comprises comparing the derivative of the acquired signal with a pulse end detecting threshold, said threshold being dynamically adapted to the noise level affecting the derivative of the acquired signal, and storing the samples of the acquired signal as long as the derivative of the acquired signal is greater than the pulse end detecting threshold.

The invention also extends to a system configured to implement this method, as well as to a computer program product including code instructions for executing this method.

### BRIEF DESCRIPTION OF DRAWINGS

Further aspects, aims, advantages and characteristics of the invention will better appear upon reading the following detailed description of preferred embodiments thereof, given by way of non-limiting example, and made with reference to the appended drawings in which:

FIGS. 1a and 1b represent a standard pulse the decrease approximation of which can be made by a decreasing exponential and an exemplary pulse pile-up, respectively;

FIG. 2 is a diagram depicting a system for processing a noisy time signal to extract pulses therefrom in accordance with a possible embodiment of the invention;

FIG. 3 is a graph depicting a method for processing a noisy time signal to extract pulses therefrom in accordance with a possible embodiment of the invention;

FIGS. 4a and 4b depict the windowing in accordance with a possible implementation of the invention corresponding to the detection of a pulse and of a pulse pile-up, respectively;

FIG. 5 represents several exemplary pulses extracted by implementing the invention of variable sizes as a function of the pulses and of the possible presence of a pile-up.

### DETAILED DISCLOSURE OF PARTICULAR EMBODIMENTS

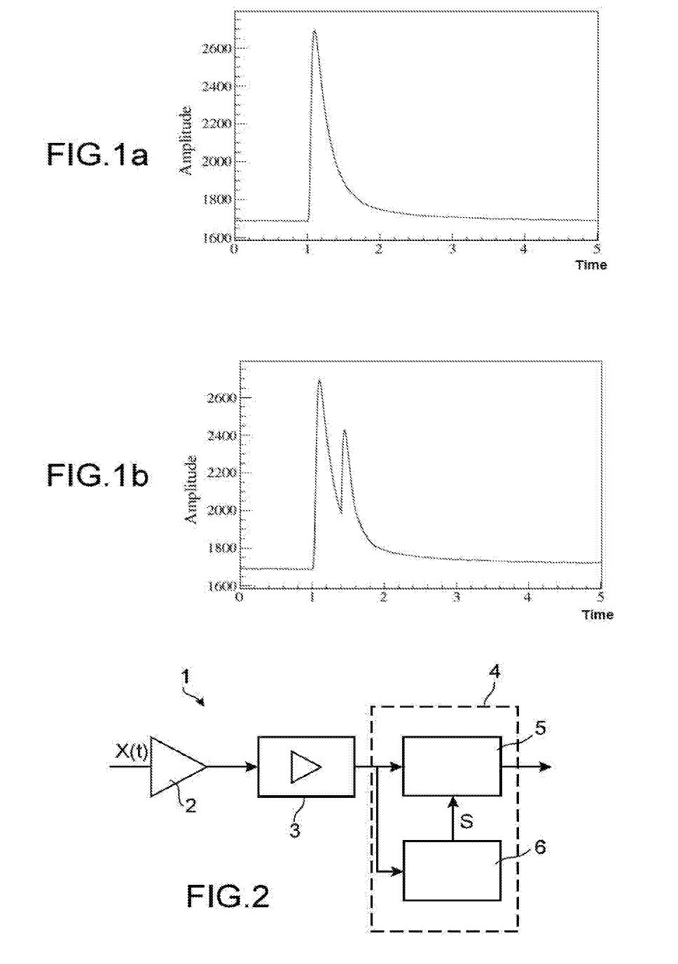

The term pulse corresponds to a charge and discharge type event of an equivalent resistor-capacitor circuit the decrease of which can be approximated by a decreasing exponential as depicted in FIG. 1a. The shape of a pulse varies according to the system and the type of event met by the detector and potential deficits caused by the detector-pre-amplifier combination upstream of the analogue-to-digital converter in charge of digitalising the analysed pulsed signal. Also, the proportionality relationship between charge and discharge can be debased by the appearance of events of delayed reactions.

The term pile-up corresponds to the appearance of several pulse events in too short a lapse of time for the circuit to have finished to totally discharge the energy of the individualities. An exemplary pile-up is depicted by FIG. 1b where two overlapping pulses can be seen.

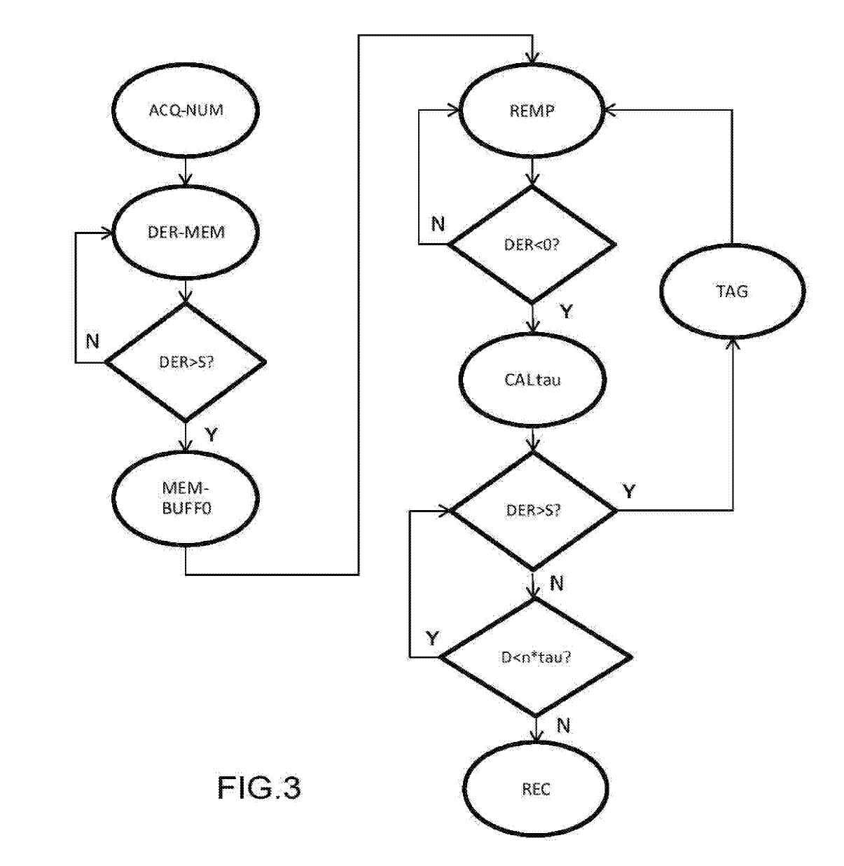

With reference to FIG. 2, the invention provides a system 1 for processing a noisy time signal X(t) having a set of pulses of different amplitude and duration, comprising a unit for processing 4 the signal configured to detect the pulses, said unit 4 being able to be disposed downstream of a pre-amplifier 2 of the signal acquired by a detector, for example a nuclear radiation detector, and of an analogue-to-digital converter 3 able to digitise the acquired signal.

It will be noticed that in the embodiment depicted in FIG. 2, the processing unit 4 is placed directly after the analogue-to-digital converter 3. Thus, the signal is not deformed by a digital pre-processing and the information extracted by the processing unit 4 retains its original characteristics.

The invention is however not limited to a purely digital implementation, but can generally be implemented analogically or digitally, as well as with a computer program code executing on a processor, on reconfigurable media such as FPGA (“Field Programmable Gate Array”) or dedicated media such as ASIC (“Application Specific Integrated Circuit”). In the following, the example of a purely digital implementation will be taken, which is a favoured but non-limiting implementation.

The processing unit 4 is more particularly configured to perform the high-pass filtering of the signal acquired by the detector and compare the acquired signal filtered by the high-pass filter with a pulse start detecting threshold to detect a pulse when the filtered acquired signal is greater than said threshold. By pulse detection, it is meant the detection of the arrival of a pulse, that is the detection of a pulse start instant in the acquired signal.

The processing unit 4 comprises a pulse detecting module 5 and a detecting threshold calculating module 6 connected to the pulse detecting module 5 to dynamically adapt the pulse start detecting threshold to the noise level affecting the acquired signal filtered by the high-pass filter.

The advantage of the high-pass filtering is to retain the high frequency components of the signal acquired by the detector the sudden variations of which are synonymous with a pulse start, and to overcome the low frequency components including the baseline of the pulses. Its advantage is further to reduce the width of the pulses, thus increasing the possibility of detecting pile-ups. A favoured implementation of such a high-pass filtering corresponds to calculating the derivative (derivation) of the signal acquired by the detector, in particular a digital derivative with a time constant when the signal acquired by the detector has been previously digitised. In the continuation of the description, reference will be made to this favoured implementation of the high-pass filtering.

The processing unit 4 is more particularly configured to implement the method described thereafter.

A first aspect of the invention provides calculating the pulse start detecting threshold in a stand-alone and dynamic way, by overcoming the characteristics of the signal-noise set to be processed. To do so, the invention is based on the derivative of the original signal in order to decide whether to consider or not the presence of a pulse. The use of the signal derivative enables both the signal to be normalised around zero since the average of the derivative is null, and also part of the pulses to be easily unpiled thanks to the mathematical properties of the derivative.

The method according to the invention thus comprises a step for calculating, by the detecting threshold calculating module 6, the standard deviation of the noise affecting the derivative of the acquired signal, the pulse start detecting threshold S used by the pulse detecting module 5 being dynamically adapted as a function of this calculated standard deviation. In particular, the arrival of a pulse (its start instant) can be declared when the derivative of the acquired signal exceeds a threshold corresponding to a predetermined multiple of the standard deviation σ of the noise affecting the derivative.

The standard deviation is measured from the variance of a portion of the signal and enables the dispersion around the average, which in this case is null, to be measured. Calculating the standard deviation must theoretically be made without the presence of pulses on the studied signal portion, the pulses influencing the result upwards. In order to meet this constraint which would impose to calibrate the threshold outside the measurement area, a favoured embodiment of the invention provides using the signal in the presence of pulses and overcoming the presence of the pulses to observe the noise and calculate the threshold.

In this embodiment, calculating the standard deviation of the noise affecting the derivative of the acquired signal can comprise smoothing the acquired signal by an ideal low-pass filter, calculating a differentiated signal by subtracting the smoothed signal from the acquired signal, this subtraction enabling a signal containing the noise alone to be obtained, deriving the differentiated signal, and finally calculating the standard deviation σ of the derived differentiated signal.

As an alternative, a non-ideal low-pas filter with an infinite pulse response is used. Two drawbacks are nevertheless to be reported. On the one hand, the response of the filter reveals a phase shift, and the subtraction of both signals can therefore contain the differences in phase shift being caused, which disrupts the measurement of the standard deviation. On the other hand, the noise can be attenuated if it is not perfectly smoothed before subtraction, thus distorting the calculation of the standard deviation. In this alternative, the invention then provides performing a first pass to calculate the standard deviation of the signal of the derivative from the difference between the original signal and the filtered original signal. A first threshold is set thanks to this first standard deviation and is used for performing a second calculation of the standard deviation on the same window of the derived original signal but without the absolute values of this derived original signal being above this first threshold. From this new standard deviation, a more accurate threshold is calculated which serves to detect the pulses.

For example, the low-pass filter performs a filtering with an exponential moving average according to which the filtered signal is s(n)=α*x(n−1)+(1−α)*s(n−1), where x(n) represents the n-th sample of the digitised acquired signal and where a represents the smoothing constant of the filter.

The differentiated signal is thus expressed as s_{diff(n)}=x(n)−s(n), and its derivative on a window of a size N is expressed as derivative_{diff(n)}=(s_{diff(n)}−s_{diff(n-N)})/N.

The standard deviation of M observations of the derivative of the differentiated signal is then

$$σ1 = \sqrt{( \frac{1}{M}} {\sum }_{n = 1}^{M} {derivative}_{diff ( n )}^{2} ) .$$

This standard deviation enables the first threshold S1 to be calculated, for example as a multiple of the standard deviation σ1: S1=α1*σ1.

A second calculation of the standard deviation on the same window of the derived original signal is then performed but without the absolute values of this derived original signal being above this first threshold S1, that is

$$σ = \sqrt{( \frac{1}{M}} {\sum }_{n = 1}^{M} {derivative}_{diff ( n )}^{2} ,$$

only for the values of the derived original signal such that |derivative_{diff(n)}|>S1. The pulse detecting threshold can then be calculated as a multiple of this standard deviation: S=α*σ.

Once the standard deviation of the noise of the studied signal portion is obtained, the use of the standard normal distribution, that is having a null average and a utility standard deviation, can be used to calculate the pulse detecting threshold S with which the digital derivative is compared. Indeed, when a signal follows a normal distribution, 99.7% of its values are between −3*the standard deviation and 3*the standard deviation of this signal. It is therefore possible to consider that a threshold S, S1 being placed at a minimum of 4*the standard deviation will be nearly always placed above the noise but also very close to the latter compared with conventional methods. In the alternative with a non-ideal low-pass filter, the first threshold S1 can be calculated in the same way, and in particular α1=α can be provided.

The application of a normal distribution for approximating the noise as being a white Gaussian noise is possible for the following reasons. In measuring the radiation of the field of nuclear instrumentation, there are conventionally two types of electronic noises: the thermal noise and the shot noise. The first is mathematically considered as a white Gaussian noise and therefore corresponds to the evaluation of the threshold by the standard normal distribution. As for the second, it occurs when the finite number of particles carrying the energy (electrons in an electronic circuit, or photons in an optical device) is low enough to give rise to discernible statistical fluctuations. Therefore, if the current or photon intensity in the circuit is too low, this noise follows a Poisson distribution which does not match the estimation by the normal distribution. However, several elements enable the set formed by the thermal noise and the shot noise to be approximated by a normal distribution. Firstly, the Poisson process converges towards a normal distribution when the number of events per second is large, which is the case for the current of a diode. Generally speaking, when an error (random variable) depends on a large number of independent causes the effects of which add up and none of which dominates, its statistical distribution converges towards a normal distribution. Due to this, the real observations of the shot noise are generally not discernible from the thermal Gaussian noise, except when there are so few elementary events (photons, electrons, etc.) that they can be individually observed. Moreover, the effect of the shot noise is such that the current very slightly fluctuates about its average value. This is similar to slow variations of current about its continuous component. For this reason, they can be assimilated to a variation of the baseline which is not a problem when using the derivative of the signal. Finally, the shot noise appears insignificant in a transistor against a thermal noise, a statistic which can be observed during the test measurements of the invention.

A second aspect of the invention further provides an also dynamic windowing of the detected pulses using the above-described pulse start detecting dynamic threshold S.

This dynamic windowing is a function of the size of the pulses and/or of the sum of pile-ups, and is based on an approximation of the decrease of a pulse (characteristic of the discharge of a capacitor) by a decreasing exponential type function. Indeed, thanks to the mathematical characteristics of the decreasing exponential it is possible, once the time constant tau of the circuit RC modelling the capacitor and corresponding to about 37% (1/e) of the height of the pulse is calculated, to predict the end of the pulse for example when the date of 5 ×tau has expired (this date corresponding to 1% of the pulse height).

This dynamic windowing thus requires a pulse peak to be located, and is based, for example, on a high-pass filtering of the signal acquired by the detector for which the local maxima of the acquired signal result in a change of sign as is the case for the derivative.

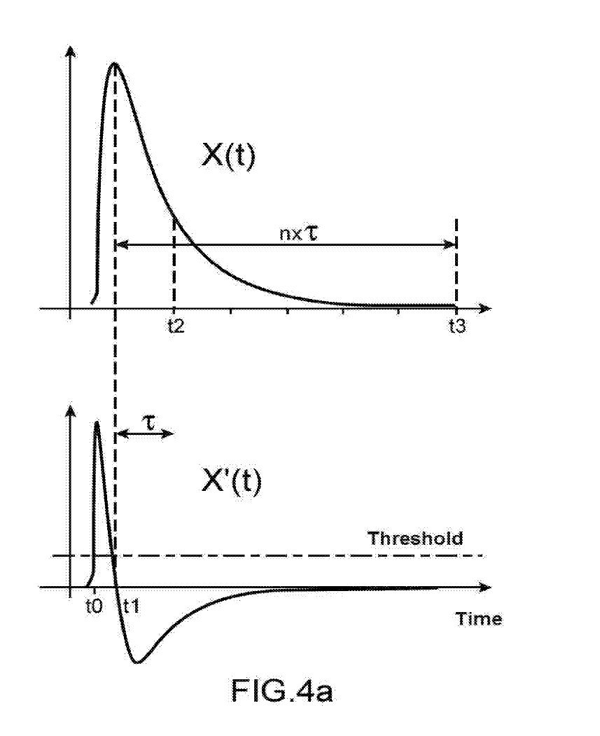

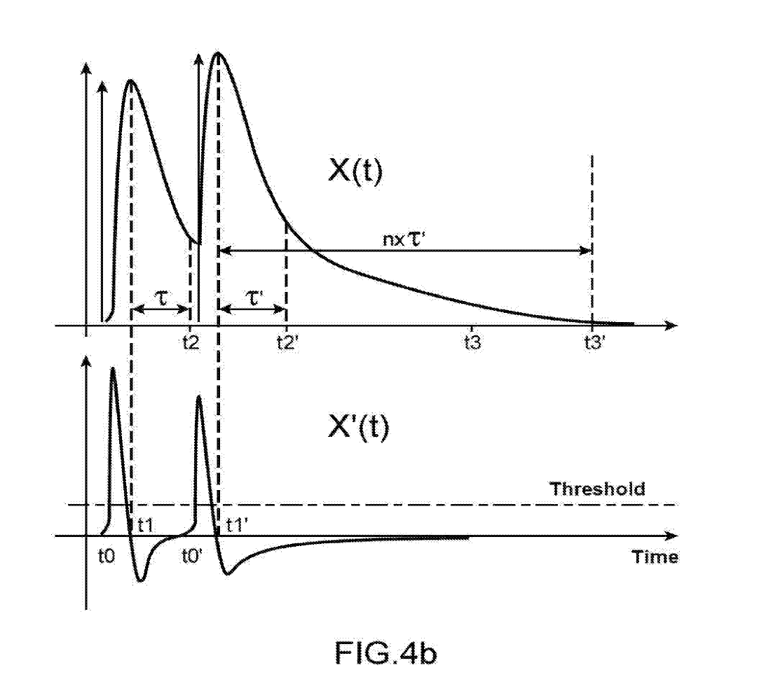

With reference to FIGS. 3, 4a and 4b, the different steps of detecting a pulse and its windowing for storing the various samples thereof in a table are as follows, herein described as part of the favoured embodiment implemented digitally and based on the calculation of the digital derivative of the digitised acquired signal.

FIGS. 4a and 4b each represent the acquired signal X(t) and its derivative X′(t) and more precisely correspond to the detection of the start instant and to the windowing of a pulse and of a pulse pile-up, respectively.

These steps are initiated by an operation “ACQ-NUM” signalling the signal acquisition start by the detector and its digitalisation by the analogue-to-digital converter. Then, during an operation “DER-MEM”, the digital derivative of the digitised acquired signal is calculated whereas the various samples of the digital acquired original signal are, in a favoured embodiment, recorded in a circular buffer of a programmable size.

The digital derivative DER is compared with the pulse start detecting dynamic threshold S and if the threshold S is exceeded which indicates the arrival of a pulse, the trailing value of the buffer is backed up during an operation “MEM-BUFFO”. With reference to FIGS. 4a and 4b, the threshold S is exceeded at a date to.

Further to detecting the pulse start instant t0, during an operation “REMP”, filling a table storing the different samples of the digitised acquired signal is performed, by taking for example for the first values, the values recorded in the buffer which precede the pulse, and then for the following values, those corresponding to the pulse.

In parallel, tracking the digital derivative DER is performed, to locate the pulse peak when the digital derivative changes sign. With reference to FIGS. 4a and 4b, the pulse peak is situated at a date t1.

Then, during an operation “CAL tau”, identifying the duration τ separating a sample of the digitised acquired signal corresponding to the pulse peak (at t1 in FIGS. 4a and 4b) and a sample of the digitised acquired signal the amplitude of which corresponds to a predetermined ratio of the amplitude of the pulse peak (at t2 in FIGS. 4a and 4b) is performed. The ratio is for example 37% when the decrease of a pulse is approximated by a decreasing exponential.

The amplitude of the pulse peak can especially be determined by comparing the amplitude of the sample of the digitised acquired signal corresponding to the pulse peak with the amplitude of a sample of the stored digitised acquired signal whereas the digital derivative is null before it exceeds the pulse start detecting threshold, and which therefore represents the baseline of the pulse. More particularly, the buffer trailing value stored during the operation “MEM-BUFFO” can be used as a basic value of the pulse and of the possible piled-up pulses.

The filling operation “REMP” of a table storing the various samples of the digitised acquired signal comprises storing samples of the digitised acquired signal which precede the pulse stored in the buffer at t0, and storing the samples of the digitised acquired signal from the sample (at t0 in FIG. 4a) corresponding to the detection of the pulse until a distant sample (at t3 in FIG. 4a) of a predetermined multiple n of said duration τ of the sample corresponding to the pulse peak. The multiple n is preferably greater than three, for example equal to 5.

Once the last sample of the window is stored (the one at n*τ of the peak), a check of the derivative can be performed to ensure that the pulse is really over. A pulse end detecting threshold lower than the pulse start detecting threshold S is used to this end, preferably a dynamic threshold which is a function of the noise level, typically a threshold having a value lower than or equal to a predetermined multiple of the standard deviation, for example 3*the standard deviation. As the case may be, the operation “REMP” of filling the table is continued as long as the absolute value of the derivative is not lower than the pulse end detecting threshold.

In a favoured embodiment, detecting a pile-up is also performed during the filling operation “REMP”. To do so, tracking the digital derivative DER is performed to detect a new pile-up pulse when the derivative passes again above the dynamic detecting threshold S. Such passage occurs at t0′ in FIG. 4b.

If such is the case, a tagging operation “TAG” of the table being filled is performed to indicate that it corresponds to an aggregate of pulses and not to a single pulse. The different previously described steps are further reiterated: waiting for the zero crossing of the derivative to locate the new pulse peak at t1′, calculating a new duration τ′ related to the decrease of the new pulse, this new duration separating a sample of the digitized acquired signal corresponding to the new pile-up pulse peak (at t1′) and a sample of a digitised acquired signal the amplitude of which corresponds to a predetermined ratio of the amplitude of the new pile-up pulse peak (at t2′), storing the samples until the end of the new pulse (at t3′), that is at least until a distant sample of a predetermined multiple of said duration τ′ of the sample corresponding to the new pile-up pulse peak, and as the case may be as long as the absolute value of the derivative is greater than the pulse end detecting threshold.

An observation of the window size before recording the table of samples can be performed to make sure that a different artefact of a pulse is not recorded. In particular, if the size of the window is lower than a minimum time resolution of a pulse produced by the combination of the detector and of the pre-amplifier, it is preferable to reject it.

It will be noticed that during the zero crossing of the derivatives, it is possible to store the date of the event. Where dating on a threshold depends on the height of the pulse, the use of the zero crossing of the derivative enables each pulse to be equally dated, independently of its height.

By dynamically adapting the size of the window to the shape of the pulse, the invention enables both a too big and a too small window sizes to be avoided. Furthermore, by separating the pulses as tables, it is possible to separate and parallelize the processings, for example on a multicore system as provided in the patent application WO 2013/135695 A1. The invention further overcomes the rejection constraint of the piled-up signals which is a problem for the short duration measurements. Indeed, the invention provides the possibility of post-processing pile-ups which are then as tagged pile-up tables as such and not truncated.

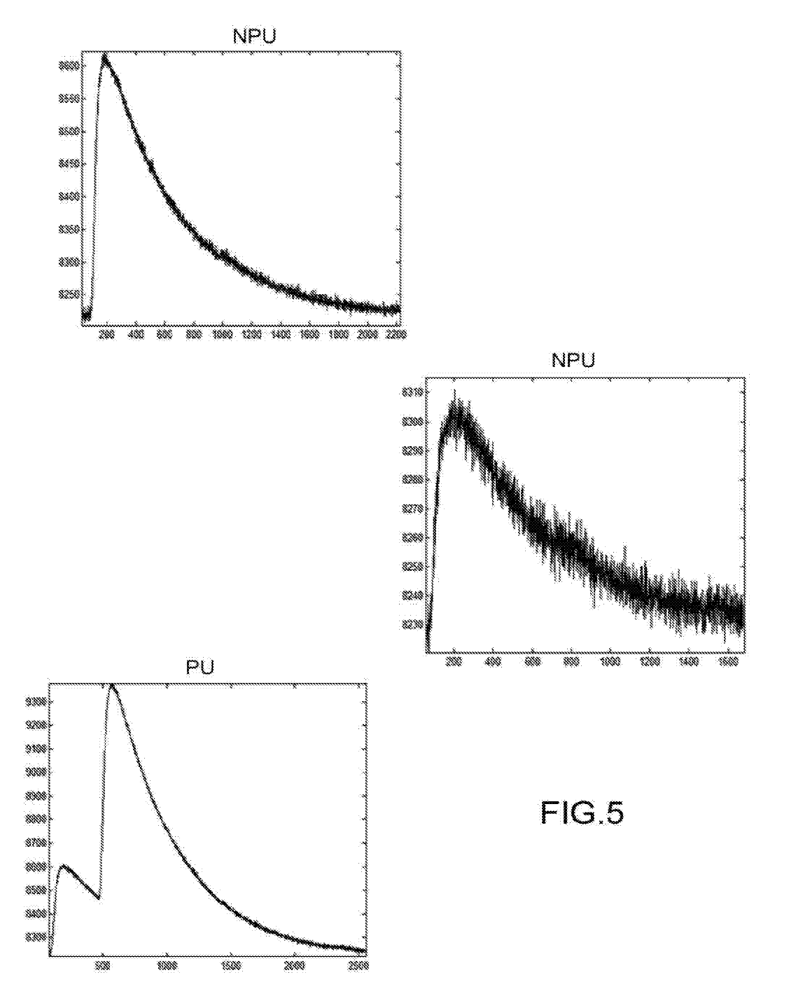

In FIG. 5 are represented three examples of pulse extraction performed by implementing the invention. These extractions are tagged as the representatives of a single pulse (NPU) or of a pile-up (PU). It will be noticed the variable size of these extractions which is a function of the extractions.

The invention is not limited to the previously described method and system, but also extends to a computer program product comprising code instructions for executing the step of processing the digitised acquired signal to detect the pulses of the method as previously described when said program is executed on a computer, for example on the processor of the processing unit 4.

1-13. (canceled)

14. A method for processing a noisy time signal having a set of pulses of different amplitude and duration, the method comprising:
processing the noisy time signal acquired by a detector to detect the pulses,
the processing comprising deriving the acquired noisy time signal and comparing the derived acquired noisy time signal with a pulse start detecting threshold to detect a pulse when the derived acquired noisy time signal is greater than the threshold,
wherein the threshold is dynamically adapted to the noise level affecting the derived acquired noisy time signal.

15. The method according to claim 14, further comprising calculating a standard deviation of the noise affecting the derived acquired noisy time signal and dynamically adapting the threshold as a function of the calculated standard deviation.

16. The method according to claim 15, wherein the calculating the standard deviation of the noise affecting the derived acquired noisy time signal comprises smoothing the acquired noisy time signal by a low-pass filter, calculating a differentiated signal by subtracting the smoothed signal from the acquired noisy time signal, deriving the differentiated signal, and calculating the standard deviation of the derived differentiated signal.

17. The method according to claim 16, further comprising calculating a first threshold from the standard deviation of the derived differentiated signal, and calculating again the standard deviation of the derived differentiated signal excluding values of the derived differentiated signal which are, in absolute value, higher than the first threshold.

18. The method according to claim 17, wherein the smoothing the acquired noisy time signal is made by exponential moving average filtering.

19. The method according to claim 14, further comprising, further to detecting a pulse, tracking the derived acquired noisy time signal to determine a location of the pulse peak.

20. The method according to claim 19, further comprising identifying a duration separating a pulse peak and an amplitude of the acquired noisy time signal corresponding to a predetermined ratio of amplitude of the pulse peak.

21. The method according to claim 20, wherein the amplitude of the pulse peak is determined by comparing the amplitude of the pulse peak with the amplitude of the acquired noisy time signal stored before the derived acquired noisy time signal exceeds the threshold.

22. The method according to claim 20, further comprising storing the acquired noisy time signal from the detection of the pulse until a predetermined multiple of the duration from the pulse peak.

23. The method according to claim 22, further comprising:
tracking the derived acquired noisy time signal during the storing to detect a new pile-up pulse when the derived acquired noisy time signal exceeds the threshold;
determining location of the peak of the new pile-up pulse;
identifying the duration separating the peak of the new pulse from an amplitude of the acquired noisy time signal corresponding to a predetermined ratio of the amplitude of the peak of the new pile-up pulse; and
storing the acquired noisy time signal until a predetermined multiple of the duration from the peak of the new pile-up pulse.

24. The method according to claim 22, further comprising:
comparing the derived acquired noisy time signal with a pulse end detecting threshold dynamically adapted to the noise level affecting the derived acquired noisy time signal; and
storing the samples of the acquired noisy time signal as long as the derived acquired noisy time signal is greater than the pulse end detecting threshold.

25. A non-transitory computer readable medium including a computer program product comprising code instructions for executing the method according to claim 14 when the program is executed on a computer.

26. A system for processing a noisy time signal having a set of pulses of different amplitude and duration, comprising:
a processor processing the noisy time signal acquired by a detector to detect the pulses,
the processor configured to perform a derivation of the acquired noisy time signal and compare the derived acquired noisy time signal with a pulse start detecting threshold to detect a pulse when the derived acquired noisy time signal is greater than the threshold,
wherein the processor is further configured to dynamically adapt the threshold to the noise level affecting the derived acquired noisy time signal.
